(19) United States
(12) Patent Application Publication
(10) Pub. No.: US 2001/0008379 A1
(43) Pub. Date: Jul. 19, 2001

(54) Programmable integrated circuit device

(76) Inventor: Norio Sugimoto, Tokyo (JP)

Correspondence Address: McGinn & Gibb, PLLC,, 8321 Old Courthouse Road, Suite 200, Vienna, VA, 22182-3817, US

(21) Appl. No.: 09/759,283

(22) Filed: Jan. 16, 2001

(30) Foreign Application Priority Data
Jan. 17, 2000 (JP) 7499/2000

(51) Int. Cl. H03K 19/177

(52) U.S. Cl. 326/41

(57) ABSTRACT

A programmable integrated circuit device, includes (a) at least two circuit areas (25₁, 25₂) in each of which elementary devices are arranged for defining a logic circuit, (b) a connector (26₁, 26₂, 27) which electrically connects adjacent circuit areas (25₁, 25₂) among the circuit areas to each other, and (c) an input unit (23, 24) arranged in each of the circuit areas (25₁, 25₂), the input unit (23, 24) receiving data used for electrically connecting the elementary devices to one another in each of the circuit areas (25₁, 25₂).

### BACKGROUND OF THE INVENTION

1. Field of the Invention

The invention relates to a programmable integrated circuit device, and more particularly to a programmable integrated circuit device including a circuit area in which a user can construct a desired circuit.

2. Description of the Related Art

A programmable integrated circuit device such as a programmable logic device (PLD) or a field programmable gate array (FPGA) can readily accomplish a user's desired logic circuit comprised of a combination circuit or a sequential circuit carrying out desired operations, in accordance with a user's program. Such a programmable integrated circuit device can construct a user's desired logic circuit at lower costs and in a shorter period than those in a gate array. In particular, a programmable integrated circuit device into which certain functions such as PCI (peripheral component interconnect) bus interface (IF) or ATM-IF (asynchronous transfer mode interface) are in advance installed and which can construct a user's desired circuit through PCI-IF or ATM-IF is quite helpful, because it reduces a user's burden of designing a circuit.

FIG. 1 illustrates a programmable logic device (PLD) as a conventional programmable integrated circuit device. The illustrated programmable logic device 5 is comprised of a substrate 10 on which components for constructing a logic device such as an AND circuit, an OR circuit or a flip-flop circuit are arranged and on which a user's desired circuit is constructed in accordance with a user's program, and a package 11 accommodating the substrate 10 therein.

A plurality of pads 12 is arranged around the substrate 10 in the package 11. The pads 12 are electrically connected to pads (not illustrated) arranged in the substrate 10. Signals are introduced into the substrate 10 through those pads, and are output from the substrate 10 through those pads.

The package 11 includes external terminals 13 outwardly extending therefrom in association with the pads 12 arranged around the substrate 10. The pads 12 are electrically connected to the associated external terminals 13. Thus, the programmable logic device mounted on a printed circuit board, for instance, can receive signals from and transmit signals to another device located outside of the package 11, through a wiring.

The substrate 10 is designed to have a core region 14 in which a logic circuit meeting with a predetermined IF standard is constructed, a user region 15 in which a user's desired logic circuit is to be programmed by a user, and an interface region 16 sandwiched between the core region 14 and the user region 15. The core region 14 is designed to have predetermined functions such as PCI bus IF or ATM-IF, for instance, and have a fixed structure with respect to a hardware. A logic circuit programmed by a user is constructed in the user region 15 through the predetermined external terminal 13.

Since the programmable integrated circuit device satisfies a predetermined IF standard, a user may construct his/her desired logic circuit in the interface region 16 such that an interface condition between the core region 14 and the interface region 16 is satisfied. As a result, a user may construct his/her desired circuit in the user region 15 other than the core region 14 having guaranteed operation and performance, under loose conditions required for meeting with general standards. This ensures significant reduction in a user's burden in designing a logic circuit.

However, performances of the core region 14 provided by a manufacturer with a hardware being fixed in a conventional programmable integrated circuit device are not always coincident with performances a user desires. To the contrary, they are frequently not coincident with each other.

The performances applied to the core region 14 are limited to commercially selected performances, resulting in that a user has to design interface functions at first to construct a his/her desired circuit, and reconstruct a circuit in order to make the circuit meet with predetermined standards. From this standpoint, there has been a need that a user could construct a his/her desired circuit in the core region 14 as well as in the interface region 16.

Japanese Patent No. 2554914 (Japanese Unexamined Patent Publication No. 63-308411), based on U.S. patent application Ser. No. 23054 filed on Mar. 6, 1987 and assigned to Altera Corporation, has suggested a programmable integrated circuit device including a combination of an EPROM look-up table and a dynamic programmable logic device (DPLD) to thereby define a look-up table programmable logic device (LTPLD).

Japanese Unexamined Patent Publication No. 10-229131, based on both U.S. patent application Ser. No. 60/028,207 filed on Oct. 10, 1996 and assigned to Altera Corporation and U.S. patent application Ser. No. 08/920,298 filed on Aug. 28, 1997 and assigned to Altera Corporation, has suggested a programmable logic integrated circuit device increasing the number of logic regions in a programmable logic device without an increase in a load exerted on a conductor connecting the logic regions to each other.

However, the above-mentioned problem remains unsolved even in those Patent and Publication.

### SUMMARY OF THE INVENTION

In view of the above-mentioned problem in the prior art, it is an object of the present invention to provide a programmable integrated circuit device including a plurality of circuit areas in which a user can construct a his/her desired circuit.

In one aspect of the present invention, there is provided a programmable integrated circuit device, including (a) at least two circuit areas in each of which elementary devices are arranged for defining a logic circuit, (b) a connector which electrically connects adjacent circuit areas among the circuit areas to each other, and (c) an input unit arranged in each of the circuit areas, the input unit receiving data used for electrically connecting the elementary devices to one another in each of the circuit areas.

The programmable integrated circuit device includes a plurality of circuit areas electrically connected to one another through the connector. In each of the circuit areas, elementary devices are arranged for constructing a logic device. The input unit receives data used for electrically connecting the elementary devices to one another. It is assumed that the programmable integrated circuit device includes a circuit producer which connects the elementary devices to one another in accordance with the thus received data in each of the circuit areas, as programmable integrated circuit devices generally do so. The circuit producer connects the elementary devices to one another in accordance with the thus received data, to thereby accomplish a user's desired circuit in each of the circuit areas.

Hence, a user can write his/her desired interface function in one of the circuit areas which function can be fixed with respect to a hardware, and construct his/her desired macro circuits in the rest of the circuit areas. Thus, a user can have a programmable integrated circuit device having functions optimal for him/her.

In addition, if the programmable integrated circuit device in which a logic circuit having guaranteed functions and characteristics is constructed in one of the circuit areas is presented to another user, the another user can omit fabrication steps and tools required for accomplishing the logic circuit.

For instance, the circuit areas may be logically divided from one another.

As an alternative, the circuit areas may be physically divided from one another.

That is, the circuit areas may be divided from one another at a substrate. By physically dividing the circuit areas, a program for arranging a wiring in each of the circuit areas may be operated in a limited area without being interfered with wiring arrangement in the other circuit areas. Thus, it would be possible to arrange a wiring optimally for accomplishing high-rate operation and complex timing operation in each of the circuit areas.

For instance, the connector includes (b1) at least one pad located in each of the circuit areas, and (b2) an electrical conductor electrically connecting the pad located in a first circuit area to the pad located in a second circuit area located adjacent to the first circuit area.

For instance, the pad may be located in the vicinity of a boundary with the adjacent circuit area.

It is preferable that the connector includes a plurality of pads located in the vicinity of and along a boundary with the adjacent circuit area.

It is preferable that at least one of the circuit areas is includes a fuse or anti-fuse type circuit.

For instance, a fuse or anti-fuse type circuit into which data can be written only once may be constructed in at least one of the circuit areas, and rewritable circuits such as a flash type circuit or an electrically erasable circuit may be constructed in the rest of the circuit areas. This ensures enhancement in reliability to the circuit areas and designability for a user.

It is preferable that the circuit areas have single input unit to be commonly used.

By designing the circuit areas to commonly use the input unit, it would be possible to reduce both the number of terminals and fabrication costs, for instance.

In another aspect of the present invention, there is provided a system of constructing a desired circuit in a programmable integrated circuit device, including (a) the above-mentioned programmable integrated circuit, (b) tools associated with the circuit areas, each of the tools producing data to be written into each of the circuit areas, and (c) writers associated with the circuit areas, each of the writers receiving the data and writing the data into each of the circuit areas.

In still another aspect of the present invention, there is provided a method of constructing a desired logic circuit in a programmable integrated circuit device, including the steps of (a) defining at least two circuit areas in the programmable integrated circuit device, elementary devices being arranged in each of the circuit areas for defining a logic circuit, (b) electrically connecting adjacent circuit areas among the circuit areas to each other, (c) inputting data used for electrically connecting the elementary devices to one another in each of the circuit areas, and (d) electrically connecting the elementary devices to one another in each of the circuit areas in accordance with the data to thereby construct a desired logic circuit in each of the circuit areas.

For instance, the circuit areas may be defined in the step (a) by being logically or physically divided from one another.

It is preferable that the step (b) includes the steps of (b1) forming at least one pad located in each of the circuit areas, and (b2) electrically connecting the pad located in a first circuit area to the pad located in a second circuit area located adjacent to the first circuit area, through an electrical conductor.

It is preferable that the data is concurrently input into the circuit areas.

There is further provided a method of constructing a desired logic circuit in a programmable integrated circuit device, including the steps of (a) defining at least two circuit areas in the programmable integrated circuit device, elementary devices being arranged in each of the circuit areas for defining a logic circuit, (b) electrically connecting adjacent circuit areas among the circuit areas to each other, (c) producing data to be written into each of the circuit areas for electrically connecting the elementary devices to one another in each of the circuit areas, by means of a tool associated with each of the circuit areas, (d) introducing the data into a writer associated with each of the circuit areas, (e) inputting the data into each of the circuit areas from the writer, and (f) electrically connecting the elementary devices to one another in each of the circuit areas in accordance with the data to thereby construct a desired logic circuit in each of the circuit areas.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 illustrates a structure of a conventional programmable integrated circuit device.

FIG. 2 illustrates a structure of a programmable integrated circuit device in accordance with an embodiment of the present invention.

FIG. 3 illustrates a data-writing operation for constructing a programmable integrated circuit device in accordance with the embodiment.

FIG. 4 illustrates a first example of a substrate of a programmable integrated circuit device.

FIG. 5 illustrates a second example of a substrate of a programmable integrated circuit device.

### DESCRIPTION OF THE PREFERRED EMBODIMENTS

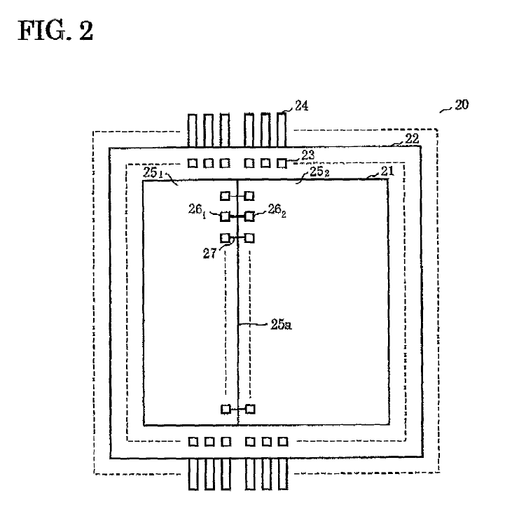

FIG. 2 illustrates a structure of a programmable logic device as a programmable integrated circuit device in accordance with a preferred embodiment of the present invention.

The programmable logic device 20 is comprised of a substrate 21 on which components for constructing a logic device such as an AND circuit, an OR circuit or a flip-flop circuit are arranged and on which a user's desired circuit is to be constructed in accordance with a user's program, and a package 22 accommodating the substrate 21 therein.

A plurality of pads 23 is arranged around the substrate 21 in the package 22. The pads 23 are electrically connected to pads (not illustrated) arranged in the substrate 21. Signals are introduced into the substrate 21 through those pads, and are output from the substrate 21 through those pads.

The package 22 includes external terminals 24 outwardly extending therefrom in association with the pads 23 arranged around the substrate 21. The pads 23 are electrically connected to the associated external terminals 24. Thus, the programmable logic device 20 mounted on a printed circuit board, for instance, can receive signals from and transmit signals to another device located outside of the package 22, through a wiring.

The substrate 21 is physically divided into a plurality of circuit areas in each of which elementary devices for constituting a desired logic circuit are arranged, and hence, a user's desired logic circuit can be programmed. In the embodiment, the substrate 21 is physically divided into first and second circuit areas 25₁ and 25₂.

The elementary devices arranged in each of the first and second circuit areas 25₁ and 25₂ are electrically connected to one another in fuse type, anti-fuse type, EE type, flash type or SRAM type. In accordance with fuse- or anti-fuse type, a user can write a program into the circuit area only once for constructing a his/her desired circuit, whereas in accordance with EE, flash or SRAM type, a user can rewrite a program in the circuit area any times, and hence, reconstruct a his/her desired circuit any times.

A plurality of pads 26₁ are mounted in the first circuit area 25₁ in the vicinity of and along a boundary 25a between the first and second circuit areas 25₁ and 25₂. Similarly, a plurality of pads 26₂ are mounted in the second circuit area 25₂ in the vicinity of and along the boundary 25a. Each of the pads 26₁ in the first circuit area 25₁ is electrically connected to the associated pad 26₂ in the second circuit area 25₂ through a metal wiring 27.

Data is input into the first circuit area 25₁ through a predetermined external terminal among the external terminals 24 extending outwardly from the package 22. Similarly, data is input into the second circuit area 25₂ through another predetermined external terminal among the external terminals 24. In the first and second circuit areas 25₁ and 25₂, the elementary devices are electrically connected to one another in accordance with data input through the predetermined external terminals, thereby user's desired circuits being constructed in each of the first and second circuit areas 25₁ and 25₂.

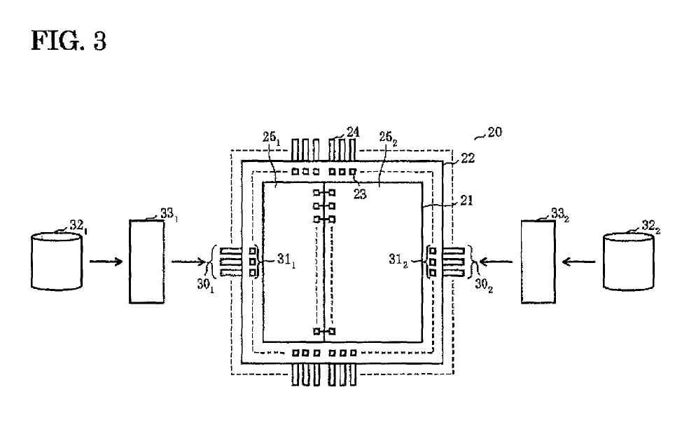

FIG. 3 illustrates a data-writing operation for constructing the programmable logic device 20.

The programmable logic device 20 is designed to include first input terminals 30₁ and second input terminals 30₂ among the external terminals 24. First pads 31₁ are formed in the package 22 around the substrate 21 in association with the first input terminals 30₁, and second pads 31₂ are formed in the package 22 around the substrate 21 in association with the second input terminals 30₂.

Data provided by a user for electrically connecting the elementary devices arranged in the first circuit area 25₁ is input into the first circuit area 25₁ through the first input terminals 30₁ and the first pads 31₁. Data provided by a user for electrically connecting the elementary devices arranged in the second circuit area 25₂ is input into the second circuit area 25₂ through the second input terminals 30₂ and the second pads 31₂.

A logic circuit producer associated with each of the first and second circuit areas 25₁ and 25₂ produces a user's desired logic circuit in each of the first and second circuit areas 25₁ and 25₂ in accordance with data written into each of the first and second circuit areas 25₁ and 25₂. The logic circuit producer is a conventional one, and a structure and an operation thereof are not to be limited to any specific ones. Hence, the logic circuit producer is not explained herein in detail.

With reference to FIG. 3, when a user constructs a his/her desired logic circuit in the first circuit area 25₁, the user produces first data 32₁ to be written into the first circuit area 25₁, by means of a first tool (not illustrated) associated with the first circuit area 25₁, and then, writes the thus produced data into a first writer 33₁. Then, the first writer 33₁ introduces the first data 32₁ into the first circuit area 25₁ through the first input terminals 30₁.

When a user constructs a his/her desired logic circuit in the second circuit area 25₂, the user produces second data 32₂ to be written into the second circuit area 25₂, by means of a second tool (not illustrated) associated with the second circuit area 25₂, and then, writes the thus produced data into a second writer 33₂. Then, the second writer 33₂ introduces the second data 32₂ into the second circuit area 25₂ through the second input terminals 30₂.

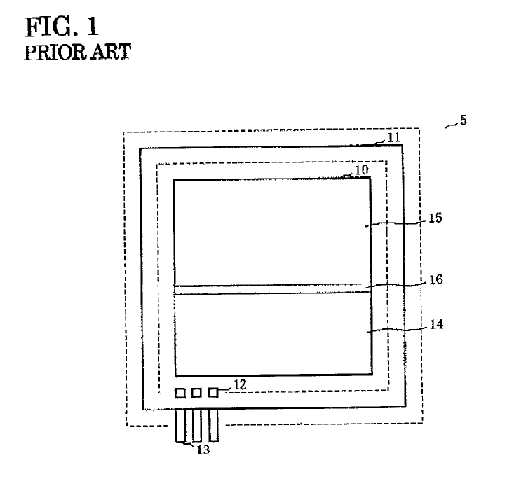

It would be possible to construct a desired logic circuit independently in each of the first and second circuit areas 25₁ and 25₂ by means of the first and second input terminals 30₁ and 30₂. For instance, if a predetermined interface function which can be fixed with respect to a hardware required by a user is written into the first circuit area 25₁, the second circuit area 25₂ may be sued as a user area such as the user area 15 illustrated in FIG. 1, in which a macro circuit may be constructed in association with the interface functions written into the first circuit area 25₁. This ensures a user a programmable logic device having optimal functions.

As an alternative, if a programmable integrated circuit device in which a logic circuit including guaranteed functions and characteristics is constructed in the first circuit area 25₁ is presented to another user, the another user can omit fabrication steps and tools required for accomplishing the first circuit area 25₁.

It is preferable to construct a programmable logic device in fuse- or anti-fuse type in a circuit area fixed with respect to a hardware, and construct a programmable logic device in EE, flash or SRAM type in other circuit areas in which user's desired logic circuits are to be constructed, for making it possible to rewrite the programmable logic device in need. This arrangement ensures enhancement reliability to the programmable logic device and designability of a user in designing a logic circuit.

When a certain system includes a circuit to be commonly used, having an already decided specification, such a circuit may be constructed in one of the first and second circuit areas 25₁ and 25₂, and other circuits having not yet decided specification different from the above-mentioned specification may be constructed in the other of the first and second circuit areas 25₁ and 25₂. Thus, even when an application specific integrated circuit (ASIC) and a programmable logic device having an interface function to ASIC are concurrently constructed in the same system or project, it is no longer necessary to design the programmable logic device to have such an interface function, ensuring significant reduction in the number of steps for fabricating a requisite circuit.

In the programmable logic device in accordance with the above-mentioned embodiment, a shape of the first and second circuit areas 25₁ and 25₂ and an area ratio between the first and second circuit areas 25₁ and 25₂ are not to be limited to those shown in the above-mentioned embodiment.

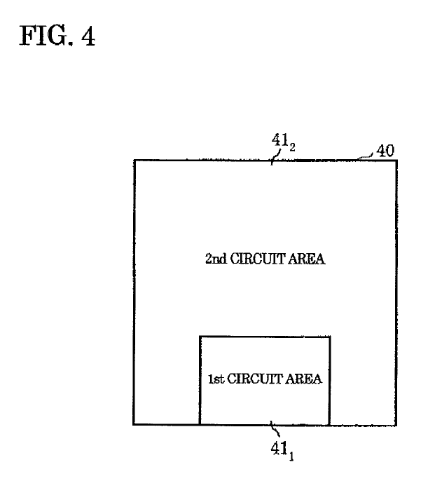

FIG. 4 illustrates a substrate in a programmable logic device in accordance with a first variant.

A substrate 40 in the first variant is divided into a first circuit area 41₁ which is rectangular and which is located making contact partially with one of sides of the substrate 40, and a second circuit area 41₂ occupying an area other than the first circuit area 41₁. A package of the programmable logic device includes pads and external terminals through which data is written into the first and second circuit areas 41₁ and 41₂. Data for constructing a user's desired logic circuit can be input independently to each of the first and second circuit areas 41₁ and 41₂.

A substrate in a programmable logic device may be divided into three or more circuit areas, in which case, pads and external terminals are formed in association with each of the circuit areas.

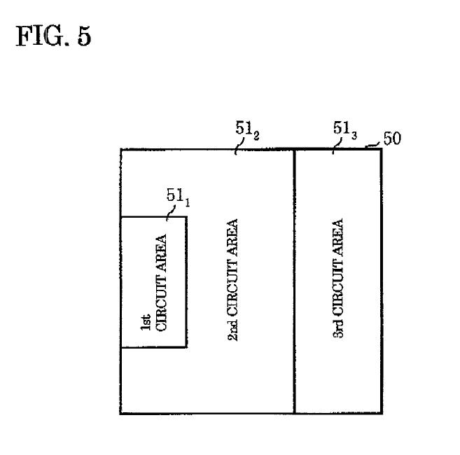

FIG. 5 illustrates a substrate in a programmable logic device in accordance with a second variant.

A substrate 50 in the second variant is divided into a first circuit area 51₁ which is rectangular and which is located making contact partially with one of sides of the substrate 50, a second circuit area 51₂ surrounding the first circuit area 51₁, and a third circuit area 51₃ which is rectangular and which makes contact with the second circuit area 51₂.

A package of the programmable logic device includes pads and external terminals through which data is written into the first to third circuit areas 51₁ to 51₃. Data for constructing a user's desired logic circuit can be input independently to each of the first to third circuit areas 51₁ and 51₃. For instance, a logic circuit which is fixed with respect to a hardware is constructed in each of the first and third circuit areas 51₁ and 51₃, and a logic circuit programmed by a user is constructed in the second circuit area 51₂.

Though the substrates 40 and 50 in the first and second variants are physically divided into a plurality of the circuit areas, the substrates 40 and 50 may be logically divided into a plurality of the circuit areas in which elementary devices for constructing a logic device are arranged.

By physically dividing the circuit areas and electrically connecting the pads in each of the circuit areas to one another, a program for arranging a wiring in each of the circuit areas may be operated in a limited area without being interfered with wiring arrangement in the other circuit areas. Thus, it would be possible to arrange a wiring optimally for accomplishing high-rate operation and complex timing operation in each of the circuit areas.

In the above-mentioned embodiment and variants, the programmable logic device is designed to include a plurality of pads and a plurality of external terminals through which data used for constructing a logic circuit is input into each of the circuit areas physically divided from one another. As an alternative, the programmable logic device may be designed to include one pad and one external terminal through which data used for constructing a logic circuit is input all the circuit areas. This ensures reduction in the number of external terminals and hence reduction in costs of fabricating the programmable logic device.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 2000-7499 filed on Jan. 17, 2000 including specification, claims, drawings and summary is incorporated herein by reference in its entirety.

What is claimed is:

1. A programmable integrated circuit device, comprising:
(a) at least two circuit areas in each of which elementary devices are arranged for defining a logic circuit;
(b) a connector which electrically connects adjacent circuit areas among said circuit areas to each other; and
(c) an input unit arranged in each of said circuit areas, said input unit receiving data used for electrically connecting said elementary devices to one another in each of said circuit areas.

2. The programmable integrated circuit device as set forth in claim 1, wherein said circuit areas are logically divided from one another.

3. The programmable integrated circuit device as set forth in claim 1, wherein said circuit areas are physically divided from one another.

4. The programmable integrated circuit as set forth in claim 1, wherein said connector includes:
(b1) at least one pad located in each of said circuit areas; and
(b2) an electrical conductor electrically connecting said pad located in a first circuit area to said pad located in a second circuit area located adjacent to said first circuit area.

5. The programmable integrated circuit as set forth in claim 4, wherein said pad is located in the vicinity of a boundary with the adjacent circuit area.

6. The programmable integrated circuit as set forth in claim 4, wherein said connector includes a plurality of pads located in the vicinity of and along a boundary with the adjacent circuit area.

7. The programmable integrated circuit as set forth in claim 1, wherein at least one of said circuit areas is includes a fuse or anti-fuse type circuit.

8. The programmable integrated circuit as set forth in claim 1, wherein said circuit areas have single input unit to be commonly used.

9. A system of constructing a desired circuit in a programmable integrated circuit device, comprising:
(a) a programmable integrated circuit device including
(a1) at least two circuit areas in each of which elementary devices are arranged for defining a logic circuit;
(a2) a connector which electrically connects adjacent circuit areas among said circuit areas to each other; and
(a3) an input unit arranged in each of said circuit areas, said input unit receiving data used for electrically connecting said elementary devices to one another in each of said circuit areas;
(b) tools associated with said circuit areas, each of said tools producing data to be written into each of said circuit areas; and
(c) writers associated with said circuit areas, each of said writers receiving said data and writing said data into each of said circuit areas.

10. The system as set forth in claim 9, wherein said circuit areas in said programmable integrated circuit device are logically divided from one another.

11. The system as set forth in claim 9, wherein said circuit areas in programmable integrated circuit device are physically divided from one another.

12. The system as set forth in claim 9, wherein said connector includes:
(b1) at least one pad located in each of said circuit areas; and
(b2) an electrical conductor electrically connecting said pad located in a first circuit area to said pad located in a second circuit area located adjacent to said first circuit area.

13. The system as set forth in claim 12, wherein said pad is located in the vicinity of a boundary with the adjacent circuit area.

14. The system as set forth in claim 12, wherein said connector includes a plurality of pads located in the vicinity of and along a boundary with the adjacent circuit area.

15. The system as set forth in claim 9, wherein at least one of said circuit areas is includes a fuse or anti-fuse type circuit.

16. The system as set forth in claim 9, wherein said circuit areas have single input unit to be commonly used.

17. A method of constructing a desired logic circuit in a programmable integrated circuit device, comprising the steps of:
(a) defining at least two circuit areas in said programmable integrated circuit device, elementary devices being arranged in each of said circuit areas for defining a logic circuit;
(b) electrically connecting adjacent circuit areas among said circuit areas to each other;
(c) inputting data used for electrically connecting said elementary devices to one another in each of said circuit areas; and
(d) electrically connecting said elementary devices to one another in each of said circuit areas in accordance with said data to thereby construct a desired logic circuit in each of said circuit areas.

18. The method as set forth in claim 17, wherein said circuit areas are defined in said step (a) by being logically divided from one another.

19. The method as set forth in claim 17, wherein said circuit areas are defined in said step (a) by being physically divided from one another.

20. The method as set forth in claim 17, wherein said step (b1) includes the steps of:
(b1) forming at least one pad located in each of said circuit areas; and
(b2) electrically connecting said pad located in a first circuit area to said pad located in a second circuit area located adjacent to said first circuit area, through an electrical conductor.

21. The method as set forth in claim 17, wherein said data is concurrently input into said circuit areas.

22. A method of constructing a desired logic circuit in a programmable integrated circuit device, comprising the steps of:
(a) defining at least two circuit areas in said programmable integrated circuit device, elementary devices being arranged in each of said circuit areas for defining a logic circuit;
(b) electrically connecting adjacent circuit areas among said circuit areas to each other;
(c) producing data to be written into each of said circuit areas for electrically connecting said elementary devices to one another in each of said circuit areas, by means of a tool associated with each of said circuit areas;
(d) introducing said data into a writer associated with each of said circuit areas;
(e) inputting said data into each of said circuit areas from said writer; and
(f) electrically connecting said elementary devices to one another in each of said circuit areas in accordance with said data to thereby construct a desired logic circuit in each of said circuit areas.

23. The method as set forth in claim 22, wherein said circuit areas are defined in said step (a) by being logically divided from one another.

24. The method as set forth in claim 22, wherein said circuit areas are defined in said step (a) by being physically divided from one another.

25. The method as set forth in claim 22, wherein said step (b) includes the steps of:
(b1) forming at least one pad located in each of said circuit areas; and
(b2) electrically connecting said pad located in a first circuit area to said pad located in a second circuit area located adjacent to said first circuit area, through an electrical conductor.

26. The method as set forth in claim 22, wherein said data is concurrently input into said circuit areas.
